(19) United States
(12) Patent Application Publication
(10) Pub. No.: US 2026/0255523 A1
(43) Pub. Date: Aug. 27, 2026

(54) ELECTRONIC COMPONENT POSITIONING FIXTURE

(71) Applicant: CHROMA ATE INC., Taoyuan City (TW)

(72) Inventors: Chun Lin WU, Taoyuan City (TW); Yu Jui CHEN, Taoyuan City (TW); Chin Yuan CHANG, Taoyuan City (TW); Chun Hao HU, Taoyuan City (TW)

(21) Appl. No.: 19/539,936

(22) Filed: Feb. 13, 2026

(30) Foreign Application Priority Data
Feb. 21, 2025 (TW) 114106453

(51) Int. Cl. H05K 7/14; E01F 15/08; F16M 11/04; F16M 11/10; G06F 1/187

(52) U.S. Cl. CPC H05K 7/1489; E01F 15/088; F16M 11/04; F16M 11/10; G06F 1/187; H05K 7/142; H05K 7/1427; H05K 7/1487

(57) ABSTRACT

An electronic component positioning fixture is adapted to position a plurality of electronic components, and includes a support tray, a push unit, and an actuator unit. The support tray supports the electronic components, and includes barrier walls to block movement of the electronic components. The push unit is coupled to the support tray, is capable of planar motion on the support tray, and pushes the electronic components so that they abut against the barrier walls. The actuator unit drives the push unit to abut against the electronic components so that they move towards and abut against the barrier walls and are each clamped between the push unit and the barrier walls.

### CROSS-REFERENCE TO RELATED APPLICATION

This application claims priority to Taiwanese Invention Patent Application No. 114106453, filed on February 21, 2025, the entire disclosure of which is incorporated by reference herein.

### FIELD

The disclosure relates to a fixture, and more particularly to a fixture for positioning an electronic component.

### BACKGROUND

Electronic components require testing during the fabrication process to ensure that they can operate normally when deployed. During the testing process, a conventional positioning fixture is used to secure multiple electronic components in position simultaneously. The conventional positioning fixture has a carrier to position the electronic components while undergoing mass production testing by testing equipment. However, the conventional positioning fixture has the following disadvantages:
1. When the conventional positioning fixture applies a pushing force to the electronic components, a downward force component is generated, which tends to cause the electronic components to tilt slightly and to move out of a level position, thereby preventing them from being flush with and securely positioned on the carrier. This ultimately interferes with the testing of the electronic components by the testing equipment.
2. Conventional positioning fixtures are often made of multiple parts stacked together. This causes tolerance stacking which prevents the precise positioning of the electronic components.
3. Conventional positioning fixtures are often made too thick which limits its compatibility with various machinery.
4. Conventional positioning fixtures require manual operation of screws when securing or releasing the electronic components which is inconvenient to operate for users.
5. Conventional positioning fixtures often include many parts and have a complicated structure which is costly to manufacture.

### SUMMARY

Therefore, an object of the disclosure is to provide an electronic component positioning fixture that can alleviate at least one of the drawbacks of the prior art.

According to the disclosure, the electronic component positioning fixture is adapted to position a plurality of electronic components. The electronic component positioning fixture includes a support tray, at least one push unit, and an actuator unit. The support tray is adapted to support the electronic components, and includes a plurality of barrier walls that are adapted to respectively block the electronic components from movement. The at least one push unit is movably coupled to the support tray and is capable of planar motion on a plane of the support tray, and is adapted to push the electronic components so that the electronic components respectively abut against the barrier walls. The actuator unit is movably coupled to the support tray. The actuator unit is configured to drive the at least one push unit to move towards and abut against the electronic components so that the electronic components respectively move towards and abut against the barrier walls and are each clamped between at least one push unit and the barrier walls.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is an exploded perspective view illustrating a first embodiment of an electronic component positioning fixture according to the present disclosure.

FIG. 2 is an exploded perspective view illustrating an actuator unit of the first embodiment.

FIG. 3 is fragmentary exploded perspective view illustrating the first embodiment.

FIG. 4 is a top view illustrating the first embodiment showing the actuator in a release position.

FIG. 5 is a fragmentary enlarged view from FIG. 4.

FIG. 6 is a fragmentary enlarged view from FIG. 4.

FIG. 7 is a fragmentary enlarged top view illustrating the first embodiment, showing the actuator unit in the release position.

FIG. 8 is a fragmentary enlarged top view illustrating the first embodiment, showing the actuator unit in a pushing position.

FIG. 9 is an exploded perspective view illustrating a second embodiment of the electronic component positioning fixture.

FIG. 10 is a fragmentary exploded perspective view illustrating the second embodiment.

FIG. 11 is a fragmentary top view illustrating the second embodiment.

FIG. 12 is a fragmentary top view illustrating the second embodiment, showing the actuator unit in the release position.

FIG. 13 is a fragmentary top view illustrating the second embodiment, showing the actuator unit in the pushing position.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

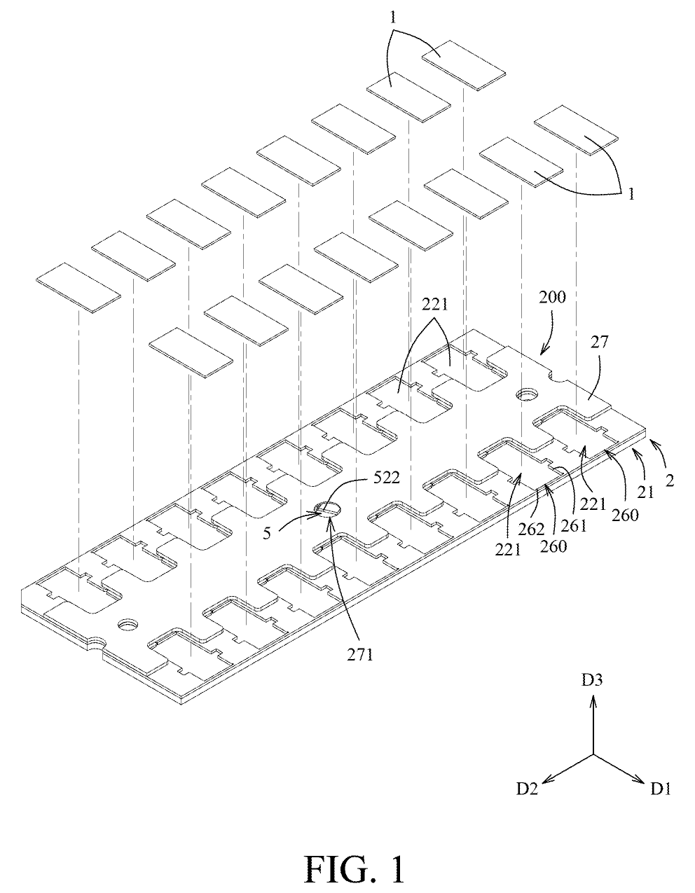

Referring to FIGS. 1 a first embodiment of an electronic component positioning fixture 200 according to the present application is adapted to position and secure a plurality of electronic components 1. Each of the electronic components 1 may be an optical communication electronic component; however, this is not a limitation of the disclosure, and the electronic components 1 may be another type of electronic component that requires positioning and securing. The electronic components 1 may, for example, have a rectangular shape; however, this is not a limitation of the disclosure.

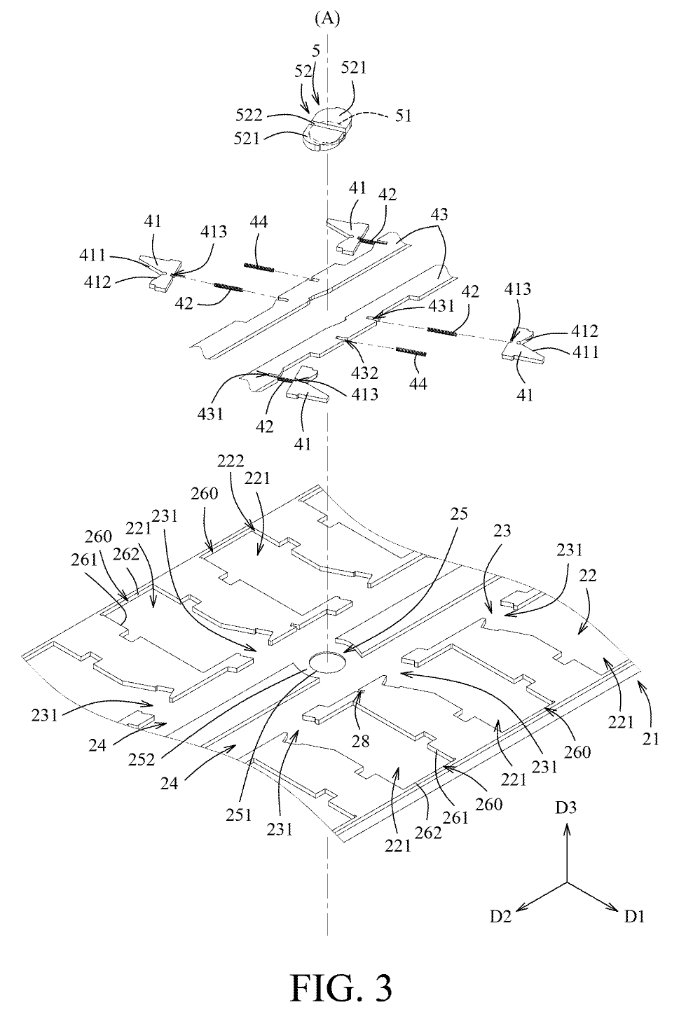

Referring to FIGS. 1, 2, 3 and 4, the electronic component positioning fixture 200 includes a support tray 2, a push module 4 and an actuator unit 5. The support tray 2 has an elongated tray plate 21 that is elongated in a lengthwise direction (D2) of the support tray 2 and has two opposite lengthwise sides 21a and two opposite widthwise sides 21b. The support tray 2 is adapted to support the electronic components 1 and includes a tray plate 21. The tray plate 21 of the support tray 2 is formed with two slot rows 22 respectively proximate to the lengthwise sides 21a, two aperture rows 23, two guide grooves 24, and a cam mounting hole 25. The two slot rows 22 each extends along the lengthwise direction (D2) and are spaced apart from each other in a widthwise direction (D1) of the support tray (2). Each of the two slot rows 22 of the support tray 2 includes a plurality of accommodation slots 221 that are arranged to be spaced apart from each other in the lengthwise direction (D2). The accommodation slots 221 have a shape that matches the shape of the electronic components 1, and they are formed just slightly larger than the electronic components 1 so as to respectively accommodate the electronic components 1. In this embodiment, each accommodation slot 221 is polygonal, for example, the accommodation slots 221 may be rectangular. The outer sides of the accommodation slot 221 in each slot row 22 is proximate to one of the lengthwise sides 21a of the tray plate 21. The two aperture rows 23 are each arranged along the lengthwise direction (D2) and are spaced apart from each other in the widthwise direction (D1). Each of the aperture rows 23 includes a plurality of apertures 231 that are spaced apart along the lengthwise direction (D2). Each of the apertures 231 is spatially communicated with a corner area of a respective one of the accommodation slots 221 that is adjacent to the inner side of the respective accommodation slots 221. The two guide grooves 24 are spaced apart from each other in the widthwise direction (D1), are located between the two slot rows of the accommodation slots 221, and are proximate to the inner sides of the accommodation slots 221. Each of the guide groove 24 is elongated along the lengthwise direction (D2) to receive a respective transmission member 43 which will be detailed hereinafter. Each of the apertures 231 of the aperture rows 23 is located between and spatially communicated with a respective one of the guide groove 24 and a respective one of the accommodation slots 221. The apertures 231 respectively and movably receive push members 41 (which will be detailed hereinafter), and guide movements of the push members 41. The cam mounting hole 25 is located in a central area of the tray plate 21 and is disposed between and spatially communicated with both of the guide grooves 24. The support tray 2 further has a plurality of slot boundaries 222 that respectively surround the accommodation slots 221, and that are arranged to be spaced apart in the lengthwise direction (D2).

The tray plate 21 of the support tray 2 is further formed with two barrier rows 26 that are spaced apart in the widthwise direction (D1) and that each extend along the lengthwise direction (D2) proximally to one of the lengthwise sides of the tray plate 21. Each of the barrier rows 26 of the support tray 2 includes a plurality of barrier walls 260 that are arranged to be spaced apart from each other in the lengthwise direction (D2). The number of barrier walls 260 is the same as the number of accommodation slots 221. Each of the barrier walls 260 is located at a periphery of a respective one of the accommodation slots 221 and is adapted to block movement of a respective electronic components 1. Particularly, each of the barrier walls 260 is located at the outer side of a respective one of the accommodation slots 221, and has a first barrier surface 261 and a second barrier surface 262 that are perpendicular to each other and that are adapted to abut against a corner of a respective one of the electronic components 1. The first barrier surface 261 and the second barrier surface 262 are respectively parallel to the widthwise direction (D1) and the lengthwise direction (D2). The first barrier surface 261 and the second barrier surface 262 of each of the barrier walls 260 are formed on a respective one of the slot boundaries 222 of the accommodation slots 221.

The support tray 2 further includes a cover plate 27. The cover plate 27 is used to cover a top surface of the tray plate 21. The cover plate 27 covers the apertures 231 and the guide grooves 24. The cover plate 27 may be attached to the top surface of the tray plate 21 via an adhesive. The cover plate 27 is formed with a cover plate hole 271 that is aligned with and spatially communicated with the cam mounting hole 25.

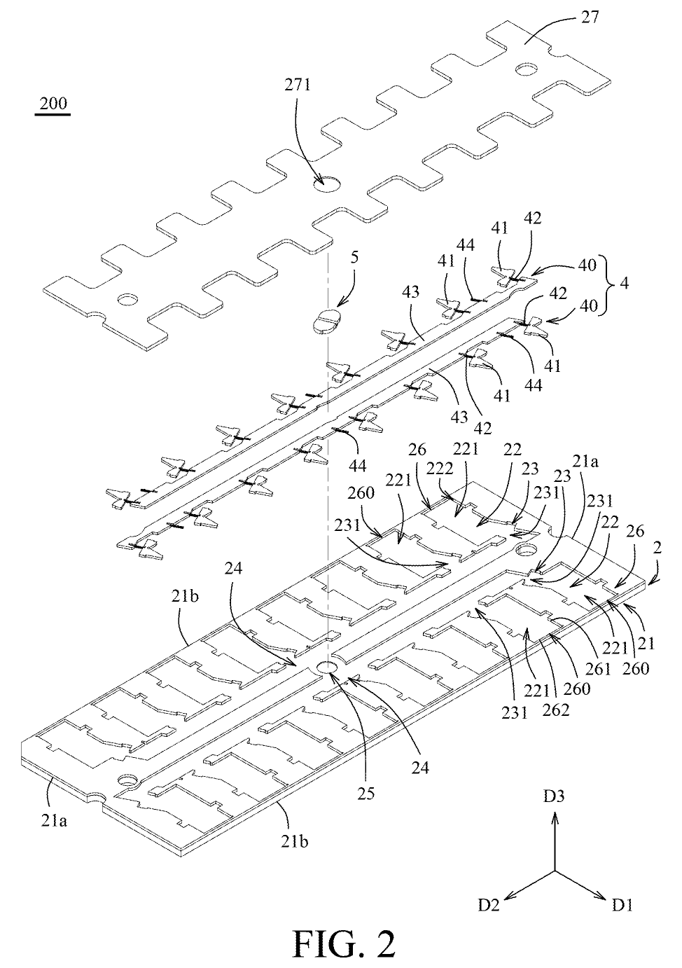

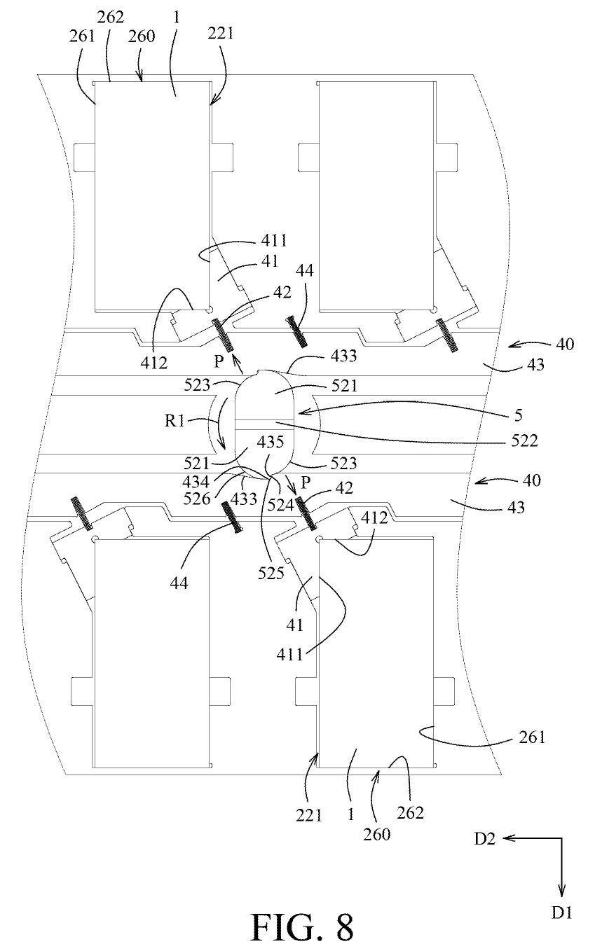

Referring to FIGS. 2, 3 and 4, in the first embodiment, the push module 4 has two push units 40 that are movably coupled to the support tray 2, are capable of planar motion on the support tray 2, and are adapted to push the electronic components 1 so that the electronic components respectively abut against the barrier walls 260. The two push units 40 are spaced apart along the widthwise direction (D1). Each of the two push units 40 is configured to move along a pushing direction (P) (see FIG. 8) so that each of the electronic components 1 abuts against the first barrier surface 261 and the second barrier surface 262 of a respective one of the barrier walls 260 and is clamped by a respective push unit 40, the first barrier surface 261, and the second barrier surface 262.

Each of the push units 40 includes a plurality of push members 41, a plurality of elastic biasing members 42, and a transmission member 43. The push members 41 are arranged to be spaced apart from each other along the lengthwise direction (D2), and connected to the transmission member 43 in a resiliently movable manner. Each push member 41 is loaded by a respective elastic biasing member 42. The push members 41 of each of the push units 40 are coupled to the support tray 2, are movable in the pushing direction (P), and are adapted to respectively abut against the electronic components 1. More specifically, the push members 41 of each of the push units 40 are respectively movably connected to the apertures 231 of a respective one of the aperture rows 23. Each of the apertures 231 guides a respective push member 41 to move in the pushing direction (P) and abut against a respective electronic component 1. The elastic biasing members 42 are arranged to be spaced apart from each other along the lengthwise direction (D2), and are configured to respectively abut against the push members 41. The elastic biasing members 42 of each of the push units 40 respectively applies a biasing force along the pushing direction (P) on the push members 41 of the respective push unit 40. The transmission members 43 of the two push units 40 are in the form of an elongated plate that extends in the lengthwise direction (D2). The transmission member 43 of each of the two push units 40 is coupled to the support tray 2. More specifically, the transmission member 43 of each of the push units 40 is movably received in a respective guide groove 24 of the support tray 2. In each push unit 40, the transmission member 43 abuts against an end of the elastic biasing members 42 that is opposite to the push member 41. Each of the guide grooves 24 guides the transmission member 43 of a respective one of the push units 40 to move along the pushing direction (P) so as to push the elastic biasing members 42 of the respective push unit 40.

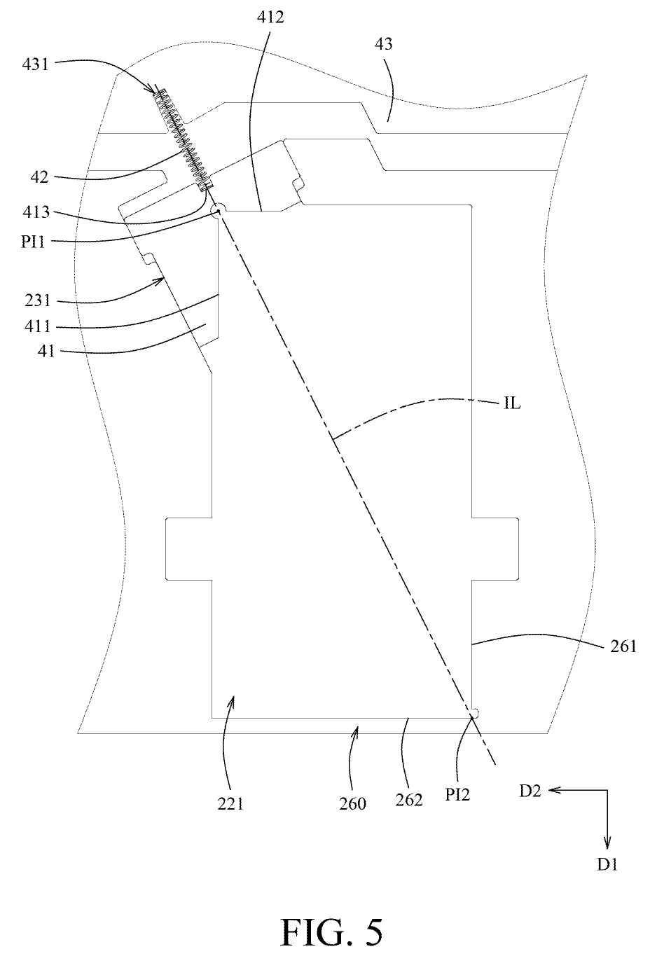

Referring to FIG. 5, the push members 41 are respectively disposed adjacent to the accommodation slots 221 of the support tray 2. Each of the push members 41 has a first push surface 411 and a second push surface 412 that are perpendicular to each other, and that both face a respective one of the accommodation slots 211. The first push surface 411 and the second push surface 412 of each of the push members 41 are respectively parallel to the first barrier surface 261 and the second barrier surface 262 of a respective one of the barrier walls 260, and are adapted for abutting against a corner of a respective one of the electronic components 1 (as shown in FIG. 1). More specifically, the first push surface 411 and the second push surface 412 of each of the push members 41 intersect at a first intersection corner (PI1). The first barrier surface 261 and the second barrier surface 262 of each of the barrier walls 260 intersect at a second intersection corner (PI2) that is spaced apart from the first intersection corner (PI1) of a respective one of the push members 41 along an imaginary diagonal line (IL) that is parallel to the pushing direction (P) (see FIG. 8). In this way, each of the push members 41 are obliquely movable in the pushing directions (P) and can abut against a respective electronic component 1 without flipping or rotating the electronic components 1.

In the first embodiment, each of the elastic biasing members 42 is positioned and extends along the imaginary diagonal line (IL) linking the first intersection corner (PI1) of a respective one of the push members 41 to the second intersection corner (PI2) of a respective one of the barrier walls 260. In each of the push units 40, each of the elastic biasing members 42 is a compression spring that has two opposite ends respectively abutting against a respective one of the push members 41 and the transmission member 43, and is deformable, extendible and compressible along the imaginary diagonal line (IL). In each of the push units 40, the push members 41 are connected to the transmission member 43 in a resiliently movable manner and are respectively loaded by the elastic biasing members 42. In this way, each of the elastic biasing members 42 are capable of exerting a pre-set biasing force on the respective push member 41. Furthermore, this set-up ensures that the biasing force exerted by each of the elastic biasing members 42 on the respective push member 41 may be evenly transmitted to the first and second push surfaces 411, 412.

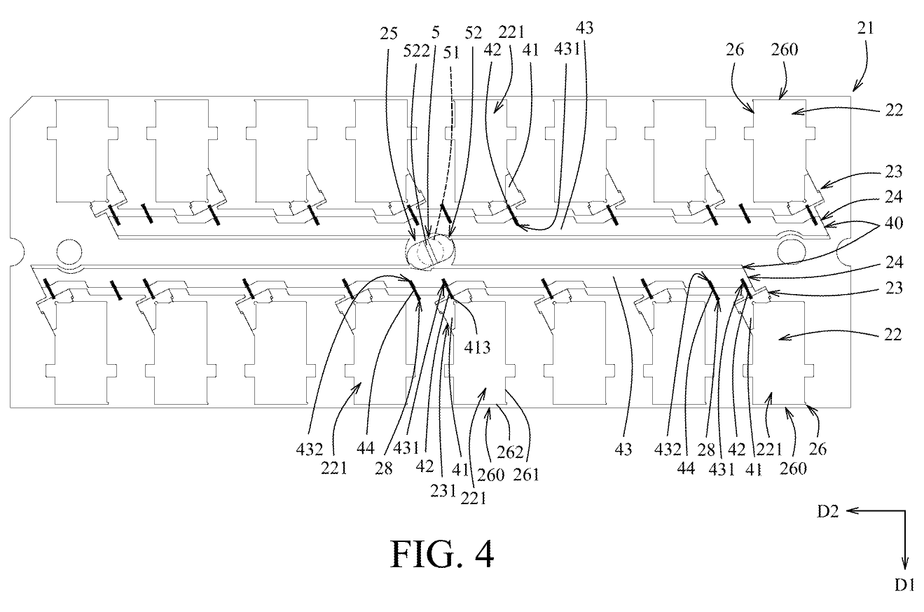

Referring to FIGS. 4 and 5, the transmission member 43 of each of the push units 40 is formed with a plurality of spring retaining sockets 431 that are spaced apart along the lengthwise direction (D2). Each of the spring retaining sockets 431 extends along a respective imaginary diagonal line (IL). Each of the push members 41 is formed with a spring retaining slot 413 extending along the respective imaginary diagonal line (IL). For each of the push units 40, each of the elastic biasing members 42 is engaged in a respective spring retaining socket 431 of the transmission member 43 and a respective spring retaining channel 413 of a respective push member 41. In this way the elastic biasing members 42 may be easily assembled and installed between the transmission member 43 and a respective push member 41 or easily disassembled. This configuration ensures that each of the elastic biasing members 42 are constrained to be positioned along the respective imaginary diagonal line (IL) after assembly and will not deviate in positon during the operation of the electronic component positioning fixture 200.

Referring to FIGS. 2, 3 and 4, each of the push units 40 further includes a plurality of returning elastic members 44. The returning elastic members 44 of each of the push units 40 is disposed between the tray plate 21 of the support tray 2 and a respective transmission member 43. The returning elastic members 44 of each of the push units 40 are configured to apply a returning force in a direction opposite to the pushing directions (P) (as shown in FIG. 8) for returning the transmission members 43 to an original position thereof. The transmission member 43 of each of the push units 40 are formed with a plurality of spring mounting slots 432 that are spaced apart along the lengthwise direction (D2). The tray plate 21 is formed with a plurality of spring mounting channels 28 that each corresponds in position to said spring mounting slots 432. Each of the returning elastic members 44 is a compression spring that has two opposite ends respectively seated in a respective spring mounting slot 432 of the transmission member 43 of each of the push units 40 and a respective spring mounting channel 28 in the tray plate 21. With this configuration, each of the returning elastic members 44 may be constrained between the transmission member 43 and the tray plate 21 and will not deviate in position.

Referring to FIGS. 1, 2, 3 and 4, the actuator unit 5 is movably coupled to the support tray 2 and is configured to drive the push units 40 of the push module 4 to move and abut against the electronic components 1 so that the electronic components 1 respectively move towards and abut against the barrier walls 260 and are each clamped between the push unit 40 and the barrier wall 260. The actuator unit 5 is operable to be rotated between a release position (see FIG. 4) and a pushing position (see FIG. 8). In the first embodiment, the cam mounting hole 25 of the tray plate 21 is configured to mount the actuator unit 5. More specifically, the actuator unit 5 is a cam that is pivotally connected to the support tray 2 for rotation about an axis (A) perpendicular to a plane of the support tray 2, and that is operable to be rotated between the release position and the pushing position. The actuator unit 5 includes a pivot body 51 and a cam 52. The cam mounting hole 25 has a pivot hole portion 251 and a cam hole portion 252. The pivot body 51 is pivotally inserted into a pivot hole portion 251 and the cam 52 is received in the cam hole portion 252. The transmission member 43 is disposed adjacent to the cam mounting hole 25 so as to be moved by the cam 52 for pushing the push members 41. The cam 52 is formed above the pivot body 51 and is positioned above and covers the pivot hole portion 251. The cover plate hole 271 of the cover plate 27 is situated immediately above the cam 52. The cam 52 of the actuator unit 5 includes two cam portions 521 that are disposed opposite to each other. Each of the two cam portions 521 is configured to drive the transmission member 43 of a respective push unit 40. More specifically, the transmission member 43 of each of the push units 40 is coupled to the support tray 2, and is disposed between the elastic biasing members 42 and the actuator unit 5. The transmission members 43 are configured to be driven by the actuator unit 5 to respectively move along the pushing directions (P) and push the elastic biasing members 42 (see FIG. 8). The cam 52 of the actuator unit 5 is formed with a drive slot 522 that is located between the two cam portions 521 and that is exposed from the cover plate hole 271. An assist tool (not shown) may be used to extend into the cover plate hole 271 and engage the drive slot 522 exposed from the cover plate hole 271 and rotate the actuator unit 5 between the release position and the pushing position. When the actuator unit 5 is in the release position, each of the two cam portions 521 of the actuator unit 5 does not push the respective transmission member 43 of each of the push units 40, and when the actuator unit 5 is in the pushing position, each of the two cam portions 521 of the actuator unit 5 pushes and drives the respective one of the transmission members 43 of the push units 40, and the push members 41 of each of the push units 40 will abut against the electronic components 1.

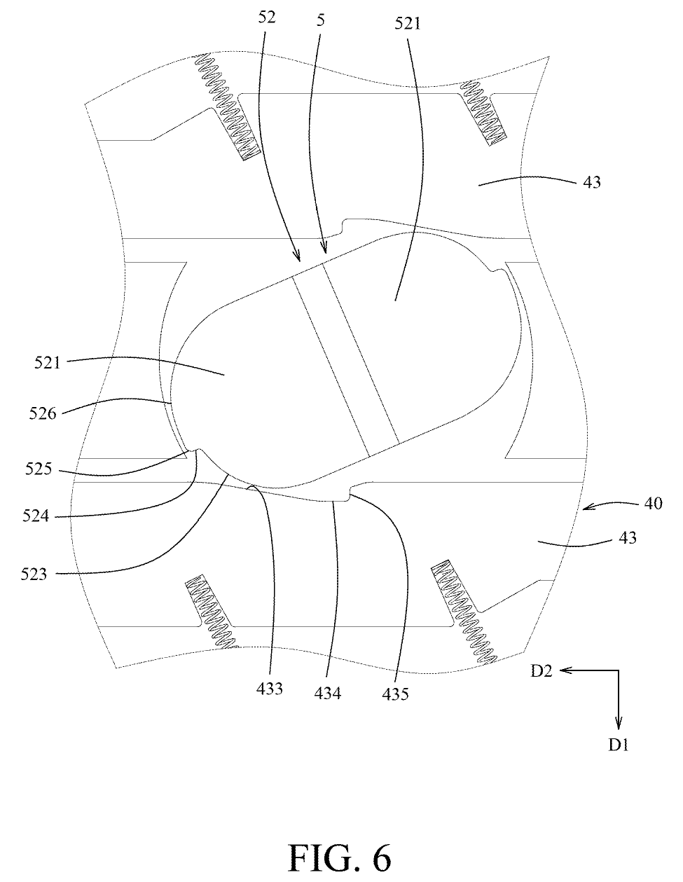

Referring to FIG. 6, in particular, the transmission member 43 of each of the push units 40 includes a slanted surface 433, a deep pressure-receiving surface 434 connected to an end of the slanted surface 433, and a steep stop surface 435 that protrudes from an end of the deep pressure-receiving surface 434 that is opposite to the slanted surface 433. Each of the two cam portions 521 includes a first lobe surface 523, a shoulder surface 524, a second lobe surface 525, and a third lobe surface 526. The first lobe surface 523 is for pushing and sliding along the slanted surface 433 of the respective transmission member 43. The shoulder surface 524 protrudes from and is connected to an end of the first lobe surface 523 for abutting against the steep stop surface 435 of the respective transmission member 43. The second lobe surface 525 is connected to a protruding end of the shoulder surface 524 opposite to the first lobe surface 523 for abutting against the deep pressure-receiving surface 434. The third lobe surface 526 is connected to an end of the second lobe surface 525 opposite to the shoulder surface 524. When the actuator unit 5 is in the release positon, each of the cam portions 521 does not abut against the respective transmission member 43. More specifically, in the release position, the first lobe surface 523 of each of the cam portions 521 faces the slanted surface 433 of the respective transmission member 43, and the push members 41 do not abut against the electronic components 1. When the actuator unit 5 is in the pushing position, the shoulder surface 524 of each of the cam portions 521 abuts against the steep stop surface 435 of a respective one of the transmission members 43, the second lobe surface 525 of each of the cam portions 521 abuts against the deep pressure-receiving surface 434 of the respective one of the transmission members 43, and the push members 41 respectively abut against the electronic components 1.

The operation of the electronic component positioning fixture 200 in relation to the electronic components 1 are explained in detail below.

Referring to FIGS. 1, 4 and 6, first, the assist tool (not shown) is extended into the cover plate hole 271 to operate the drive slot 522 of the actuator unit 5. The assist tool rotates the actuator unit 5 so that the actuator unit 5 is rotated to the release position. When the actuator unit 5 is in the release position, the first lobe surface 523 faces the slanted surface 433 of the transmission member 43, and the returning elastic members 44 of the push units 40 apply a returning force on the transmission members 43 so that the slanted surfaces 433 of the transmission members 43 are respectively moved closer to the first lobe surfaces 523 of the cam portions 521 of the actuator unit 5.

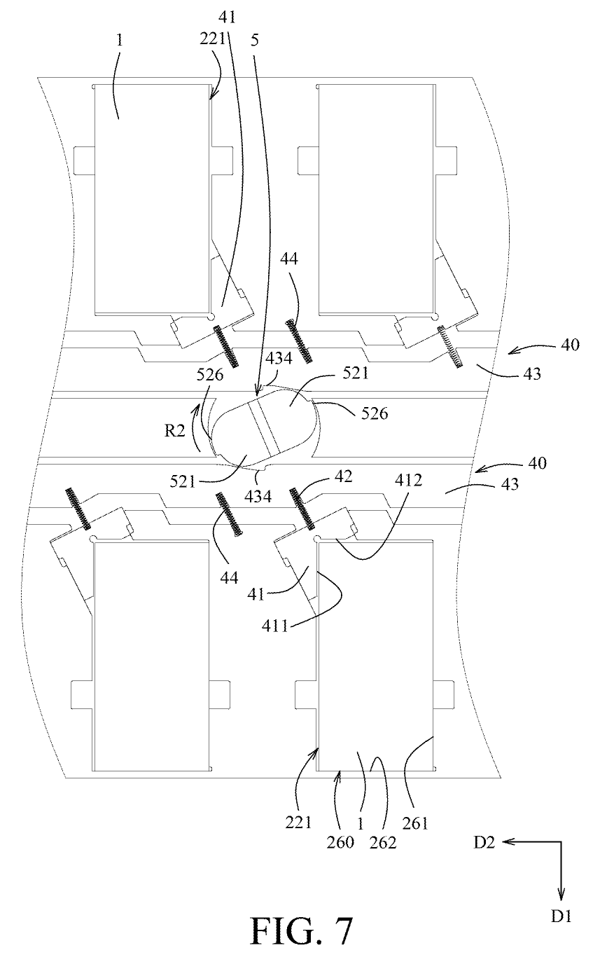

Referring to FIGS. 1 and 7, next, the electronic components 1 are respectively placed in the accommodation slots 221 of the support tray 2 of the electronic component positioning fixture 200.

Referring to FIG. 8, afterwards, the assist tool is used to rotate the actuator unit 5 in a first rotational direction (R1). When the actuator unit 5 is being rotated in the first rotational direction (R1), the first lobe surface 523 of each of the cam portions 521 will slide along and push the slanted surface 433 of a respective transmission member 43. This will cause the transmission members 43 to move away from each other. The pushing direction (P) of one of the push units 40 is opposite to the pushing direction (P) of the other one of the push units 40. Next, the second lobe surface 525 of each of the cam portions 521 will abut against the deep pressure-receiving surface 434 of the respective transmission member 43 which will cause the transmission member 43 to move further along the pushing direction (P). While the transmission members 43 are each moving along the pushing direction (P), each transmission member 43 will compress the returning elastic members 44 of a respective push unit 40 so that each of the returning elastic members 44 will deform and store a returning force. Furthermore, while the transmission members 43 move along the pushing direction (P), each transmission member 43 will push the elastic biasing members 42 of the respective push unit 40. The elastic biasing members 42 of each of the push units 40 will respectively abut against and apply a biasing force along the pushing direction (P) on the push members 41 of that push unit 40. When the push members 41 of each of the push unit 40 are moved along the pushing direction (P), the first push surface 411 and the second push surface 412 of each of the push members 41 will abut against a respective one of the electronic components 1. More specifically, the first push surface 411 and the second push surface 412 of each of the push members 41 abut the respective electronic component 1 with a force in a direction parallel to one of the imaginary diagonal lines (IL) (see FIG. 5). This force may be resolved into two component forces respectively from the first push surface 411 and the second push surface 412. The two component forces are directed in two directions respectively parallel to the widthwise direction (D1) and the lengthwise direction (D2). In this way, the first push surface 411 and the second push surface 412 of each of the push members 41 abut against the respective electronic components 1. Each of the electronic components 1 will move in the plane of the support tray 2 towards the first barrier surface 261 and the second barrier surface 262 of a respective barrier wall 260. This prevents the electronic components 1 from flipping and rotating when they are respectively pushed by the push members 41.

When each of the electronic components 1 are abutted against and are blocked by the first barrier surface 261 and the second barrier surface 262 of the respective barrier walls 260, the electronic components 1 are not able to move further and are respectively affixed by the barrier walls 260. However, since after the electronic components 1 are respectively affixed by the barrier walls 260 each of the cam portions 521 will continue to drive the respective transmission member 43 to move along the pushing direction (P), the elastic biasing members 42 of each of the push units 40 will continue to be compressed by the respective transmission member 43 and each will store a returning force. And the stored returning force of each of the elastic biasing members 42 will respectively be applied on the push members 41 to bias the push members 41 of the push unit 40. In this way, the first push surface 411 and the second push surface 412 of each of the push members 41 may bias the respective electronic component 1 with more biasing force. Therefore, the push members 41 and the respective barrier walls 260 may mitigate any accumulated tolerances relative to the electronic components 1 and securely fix the electronic components 1 in place.

When the actuator unit 5 is rotated to the position as shown in FIG. 8, the actuator unit 5 is in the pushing position. In the pushing positon, the shoulder surface 524 of each of the cam portions 521 abut against and is blocked by the steep stop surface 435 of the respective transmission member 43. This prevents the actuator unit 5 from rotating any further and secures it in the pushing position. Furthermore, in the pushing position, the second lobe surface 525 of each of the cam portions 521 abuts against the deep pressure-receiving surface 434 of the respective transmission member 43. This secures the positioning of the transmission member 43, the elastic biasing members 42, and the push members 41 in each push unit 40 at the positions shown in FIG. 8. This set-up allows the electronic component positioning fixture 200 to securely clamp and hold the electronic components 1 so that a test equipment (not shown) may be used to conduct tests on the electronic components 1 held by the electronic component positioning fixture 200.

Referring to FIGS. 6 and 7, after finishing conducting tests on the electronic components 1 held by the electronic component positioning fixture 200, the assist tool is used to rotate the actuator unit 5 in a second rotational direction (R2) that is opposite to the first rotational direction (R1). When the actuator unit 5 is being rotated in the second rotational direction (R2), the third lobe surface 526 of each of the cam portions 521 will move away from the slanted surface 433 of the respective transmission member 43. The returning forces of the returning elastic members 44 of the push units 40 cause the transmission members 43 to return, thereby allowing each transmission member 43 to move in a direction opposite to in the pushing direction (P) (see FIG. 8) so that the transmission members 43 of the push units 40 move closer to each other and return to their initial positions. When the transmission members 43 are returning to the initial positions, the elastic biasing members 42 will respectively drive the push members 41 to return. When the actuator unit 5 is rotated in the second rotational direction (R2) and reaches the release position shown in FIG. 7, for each of the push units 40, the transmission member 43, the elastic biasing members 42 and the push members 41 will return to their positions shown in FIG. 7. At this state, the electronic components 1 may be removed from the accommodation slots 221.

Referring to FIGS. 1, 2 and 8, by virtue of the push units 40 of the push module 4 being capable of planar motion in the support tray 2, the push units 40 may abut against the electronic components 1 without creating any component force in the vertical direction (D3). This prevents the electronic components 1 from warping, and allows the electronic component positioning fixture 200 to securely clamp the electronic components 1 in a planar position which allows the electronic components 1 to be tested without hindrance.

By having the actuator unit 5 to drive the push units 40 of the push module 4 so that the electronic components 1 are each clamped between the push units 40 and the barrier walls 260, the actuator unit 5 can function to support the push units 40, thereby allowing the push units 40 and the barrier walls 260 to securely clamp the electronic components 1.

In each of the push units 40, by having the elastic biasing members 42 to respectively abut against and applying a biasing force along the pushing direction (P) on the push members 41, each of the push members 41 and the respective barrier walls 260 may help mitigate the accumulated position tolerances relative to the respective electronic component 1 and securely clamp the respective electronic component 1. In this way, the electronic component positioning fixture 200 may position the electronic components 1 with good precision.

By having the push unit 40 of the push module 4 movably coupled to the support tray and capable of planar motion on the support tray 2, and by having the actuator unit 5 pivotally connected to the support tray and capable of planar rotation on the support tray 2, the electronic component positioning fixture 200 may be made thinner in the vertical direction (D3) which would improve its flexibility and widen its applicability to various different test performing environments.

In the electronic component positioning fixture 200, by having the actuator unit 5 operable to be rotated between the release position and the pushing position to respectively release or clamp the electronic components 1, the electronic component positioning fixture 200 is easy to operate and convenient for an operator.

In the electronic component positioning fixture 200, by having the actuator unit 5 to push and drive the push units 40 of the push module 4 to abut against the electronic components 1, the electronic component positioning fixture 200 may be manufactured with fewer separate components which would lower the manufacturing cost of the electronic component positioning fixture 200.

By designing the support tray 2 to be formed with the two slot rows 22, the two aperture rows 23, the two guide grooves 24, and the two barrier rows 26, and by designing the push unit 40 of the push module 4 as related above, the components of the electronic component positioning fixture 200 are arranged in a very dense layout. In this way, the size of the electronic component positioning fixture 200 may be minimized.

It should be noted that the electronic component positioning fixture 200 of the first embodiment may have different variations as related below.

In one variation of the first embodiment, the support tray 2 is formed with only one slot row 22, one aperture slot row 23, one guide groove 24, and one barrier row 26, the push module 4 only has one push unit 40, and the actuator unit 5 only includes one cam portion 521.

In another variation of the first embodiment, the support tray 2 only has one accommodation slot 221, and one barrier wall 260, and is only formed with one guide groove 24 and one aperture row 23 which has only one aperture 231. Furthermore, in this variation, the push unit 40 of the push module 4 has only one push member 41, one elastic biasing member 42, one transmission member 43, and one returning elastic member 44, and the actuator unit 5 only has one cam portion 521.

In yet another variation of the first embodiment, the actuator unit 5 is a slide member that is connected to the cam mounting hole 25 and that is slidable in the direction parallel to the plane of the support tray 2. In this variation, the actuator unit 5 may have a slope surface, and when the actuator unit 5 makes a sliding motion, the slope surface is able to cam or push the respective transmission member 43 to move in the pushing direction (P).

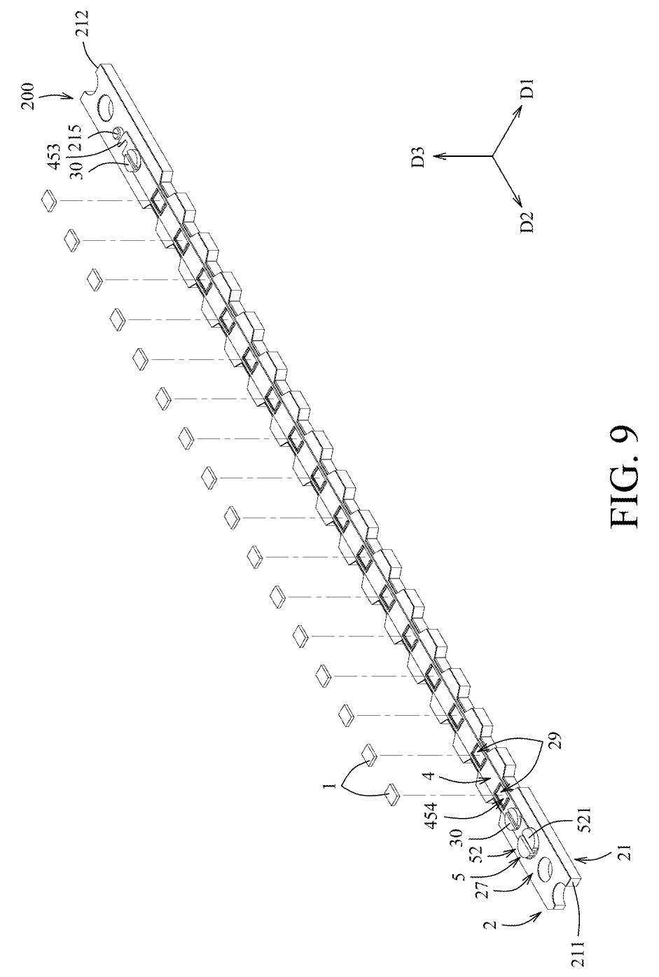

Referring to FIGS. 9, a second embodiment of the electronic component positioning fixture 200 is similar to the first embodiment; however, the differences in structure will be described below.

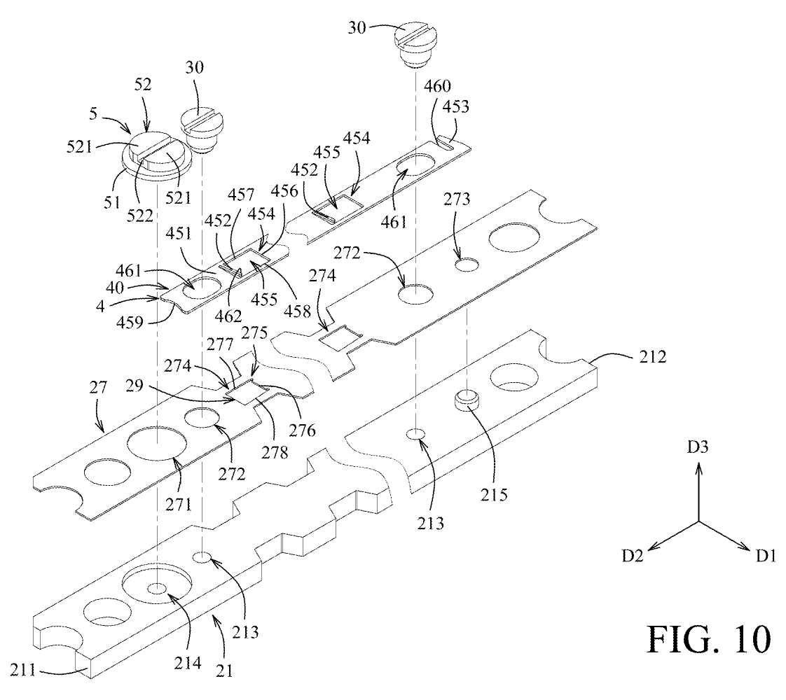

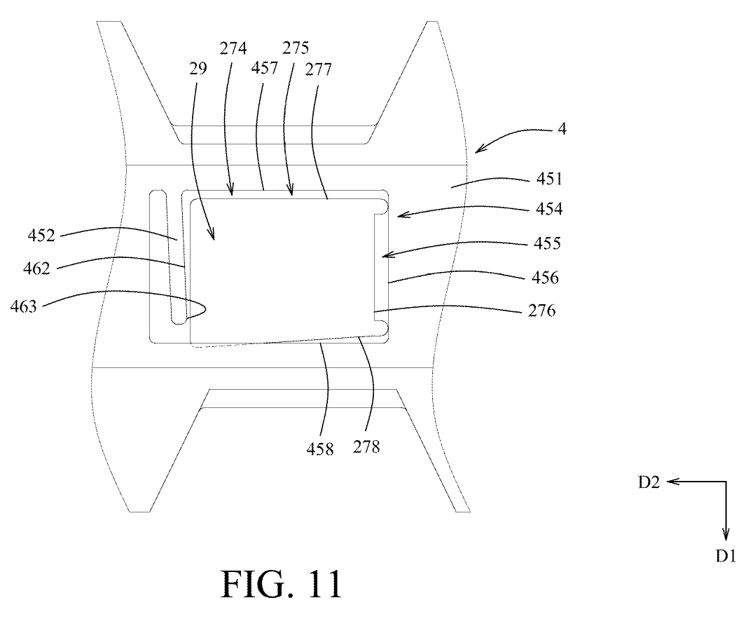

Referring to FIGS. 9, 10 and 11, the tray plate 21 of the support tray 2 has a first end 211 and a second end 212 that are disposed opposite to each other and spaced apart along the lengthwise direction (D2). The tray plate 21 of the support tray 2 has two connection holes 213 that are respectively proximate to the first end 211 and the second end 212, and a cam mounting hole 214 that is disposed between the first end 211 and the respective connection hole 213. The tray plate 21 of the support tray 2 further has a blocking post 215. The blocking post 215 is located between the second end 212 and the respective connection hole 213. The cover plate 27 of the support tray 2 is formed with a cover plate hole 271 that is aligned and spatially communicated with the cam mounting hole 214, two first through holes 272 that are respectively aligned and spatially communicated with the two connection holes 213, and a second through hole 273 that is aligned with and that receives the blocking post 215. The cover plate 27 includes a plurality of slot boundaries 274 that are spaced apart along the lengthwise direction (D2). The slot boundaries 274 and the tray plate 21 cooperatively define a plurality of accommodation slots 29 to respectively receive the electronic components. The slot boundaries 274 respectively surround the accommodation slots 29 and are arranged along and spaced apart in the lengthwise direction (D2). Each of the slot boundaries 274 has a barrier wall 275 that is located on a periphery of a respective one of the accommodation slots 29. The barrier wall 275 has a first barrier surface 276 and a second barrier surface 277 that are perpendicular to each other and that are adapted to block movement of a respective electronic component 1. In this embodiment, the first barrier surface 276 and the second barrier surface 277 are respectively parallel to the widthwise direction (D1) and the lengthwise direction (D2). The slot boundaries 274 of the cover plate 27 of the support tray 2 further includes a plurality of oblique guiding surfaces 278, respectively. Each of the oblique guiding surfaces 278 is located at the periphery of a respective accommodation slot 29. More specifically, each of the oblique guiding surfaces 278 faces the second barrier surface 277 of a respective one of the barrier walls 275 and is located at an end of the first barrier surface 276 that is opposite to the second barrier surface 277 of the respective one of the barrier walls 275. Each of the oblique guiding surfaces 278 extends towards the first barrier surface 276 and the second barrier surface 277 of the respective one of the barrier walls 275 and is configured to guide movement of the electronic component 1 towards the first barrier surface 276 and the second barrier surface 277 of the respective one of the barrier wall 275.

The support tray 2 further has two guiding posts 30. Each of the guiding posts 30 passes through a respective first through hole 272 and a respective connection hole 213. In the second embodiment, each of the connection holes 213 may be a screw hole, and each of the guiding post 30 may be a screw that is screwed into the respective connection hole 213.

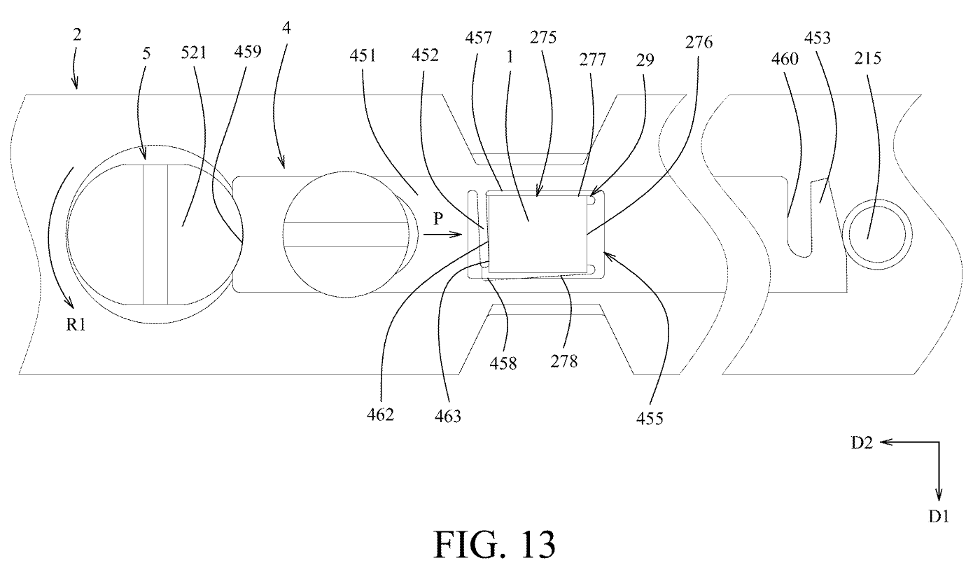

Referring to FIGS. 9 to 12, the push unit 40 of the push module 4 is made of the same material and formed as one single piece. In the second embodiment, the push unit 40 of the push module 4 may be, for example, a single piece stainless steel component. The push unit 40 is an elongated plate and extends along the lengthwise direction (D2). The push unit 40 includes a transmission member 451, a plurality of push members 452, and a returning elastic member 453. The transmission member 451 is disposed on top of the cover plate 27 of the support tray 2. The transmission member 451 is configured to be driven by the actuator unit 5 to drive movement of the push members 452 in the pushing direction (P) (see FIG. 13). The transmission member 451 has a plurality of open slot boundary edges 454 that are arranged along and spaced apart in the lengthwise direction (D2). The transmission member 451 further has a plurality of open slots 455 respectively defined by the open slot boundary edges 454. The open slots 455 are respectively formed on top of the accommodation slots 29 and are aligned and spatially communicated with the accommodation slots 29 to respectively receive the electronic components 1. Each of the open slot boundary edges 454 has a primary boundary edge 456, a first boundary edge 457, and a second boundary edge 458. The first boundary edge 457 and the second boundary edge 458 are respectively connected to opposite ends of the primary boundary edge 456 and are respectively located on two opposite ends of the respective open slot 455. The primary boundary edge 456 is located on a rear end of the respective open slot 455 and is located proximate to the first barrier surface 276 of a respective one of the barrier walls 275. The first boundary edge 457 is located proximate to the second barrier surface 277 of the respective one of the barrier walls 275. The second boundary edge 458 is located proximate to the oblique guiding surface 278 of the respective one of the barrier walls 275. The first barrier surface 276 and the second barrier surface 277 of each of the barrier walls 275 are located on a respective one of the slot boundaries 274.

The transmission member 451 includes a pressure bearing surface 459 and an end surface 460 that are opposite to each other and that are spaced apart along the lengthwise direction (D2). The pressure bearing surface 459 is located at an end of the transmission member 451. More specifically, the pressure bearing surface 459 and the end surface 460 are respectively proximate to the first end 211 and the second end 212. The pressure bearing surface 459 is configured to be pushed by one of the cam portions 521 of the actuator unit 5. The transmission member 451 is formed with two slide grooves 461 that are respectively located proximate to the pressure bearing surface 459 and the end surface 460. Each of the slide grooves 461 extends along the lengthwise direction (D2). Each of the guiding posts 30 passes through a respective slide groove 461, and guides and restricts movement of the respective slide groove 461 to move in the pushing direction (P).

The push members 452 are respectively connected to the open slot boundary edge 454 of the transmission member 451 in a resiliently movable manner. Each of the push members 452 are respectively formed in the open slot 455. The push members 452 are arranged along and spaced apart in the lengthwise direction (D2) and are configured to respectively abut against the electronic components 1. In the second embodiment, each of the push members 452 is integrally formed on the transmission member 451 in the form of a spring arm. Each of the push members 452 extends obliquely from the first boundary edge 457 towards the primary boundary edge 456 and the second boundary edge 458 of a respective one of the open slots 455. Each of the push members 452 has an oblique abutting surface 462 that faces the primary boundary edge 456 of the respective one of the open slots 455 and that is adapted to push the electronic components 1. The oblique abutting surface 462 has a pushing portion 463 that is proximate to the second boundary edge 458 and that is for pushing the electronic components 1.

The returning elastic member 453 is disposed at another end of the transmission member 451 opposite to the pressure bearing surface 459. In this embodiment, the returning elastic member 453 is an integrally formed spring arm that is located on the end surface 460 of the transmission member 451. The returning elastic member 453 abuts against the blocking post 215 of the support tray 2 and is configured to bias the transmission member 451 in a direction that is opposite to the pushing direction (P) for returning the transmission member 451 to an original position thereof.

The pivot body 51 of the actuator unit 5 is pivotally mounted in the cam mounting hole 214 and partially covered by the cover plate 27. The cam 52 of the actuator unit 5 is inserted into the cover plate hole 271 for rotation about the axis (A) perpendicular to the plane of the support tray 2 and protrudes above the cover plate 27. The transmission member 451 is disposed adjacent to the cam 52. The cam portion 521 of the cam 52 is used to push the transmission member 451 so that the transmission member 451 moves along the pushing direction (P). It should be noted that in the second embodiment, only one cam portion 521 of the cam 52 is used for pushing the transmission member 451, and further description of the other cam portion 521 will be omitted hereinafter.

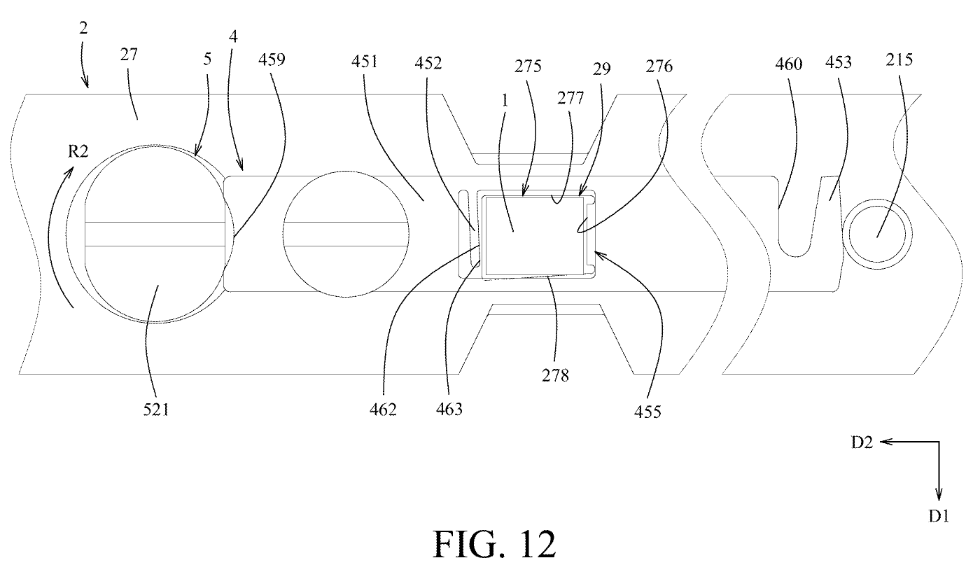

Referring to FIG. 9 and 12, when the actuator unit 5 is in the release position, the cam portion 521 does not push the transmission member 451, and the push members 452 do not push the respective electronic components 1. Furthermore, in the release position, each push member 452 is located in front of a respective accommodation slot 29 and does not block the respective accommodation slot 29. When the actuator unit 5 is in the release position, each electronic component 1 may be placed in the respective open slot 455 and the respective accommodation slot 29.

Referring to FIGS. 9, 12 and 13, when a user wishes to operate the electronic component positioning fixture 200 to secure the electronic components 1, the user uses an assist tool to rotate the actuator unit 5 in the first rotational direction (R1). When the actuator unit 5 is being rotated in the first rotational direction (R1), the cam portion 521 pushes the transmission member, and the push members 452 respectively push the electronic components 1. More specifically, the cam portion 521 of the cam 52 of the actuator unit 5 pushes the pressure bearing surface 459 of the transmission member 451 so that the transmission member 451 drives the push members 452 and the returning elastic members 453 to move in the pushing direction (P). When the push members 452 are pushed in the pushing direction (P), the oblique abutting surface 462 of each of the push members 452 will push a respective electronic component 1. More specifically, the oblique abutting surface 462 of each of the push members 452 pushes the respective electronic component 1 via the pushing portion 463 that is proximate to the second boundary edge 458. Because the pushing portion 463 of the oblique abutting surface 462 applies an oblique pushing force on the respective electronic component 1 that can be resolved into two component forces that are respectively parallel to the widthwise direction (D1) and the lengthwise direction (D2). This ensures that the pushing force applied to the respective electronic component 1 allows a two dimensional planar motion of the respective electronic component 1 towards the first barrier surface 276 and second barrier surface 277. Furthermore, when the electronic component 1 is pushed by the pushing portion 463 of the oblique abutting surface 462, the electronic component 1 will contact the respective oblique guiding surfaces 278 and be guided by the oblique guiding surface 278 to move towards the first barrier surface 276 and second barrier surface 277 on the plane of the support tray 2. In this way, the respective electronic component 1 may be guided to move towards the first barrier surface 276 and the second barrier surface 277 on the plane of the support tray 2 by the oblique abutting surface 462.

On the other hand, the returning elastic member 453 abuts against the blocking post 215 and may be pressed by the blocking post 215. In other words, while the transmission member 451 drives the returning elastic member 453 to move along the pushing direction (P), the returning elastic member 453 will be compressed and deformed by the blocking post 215 and store a returning force.

When each of the electronic components 1 is moved to abut against the first barrier surface 276 and the second barrier surface 277 of a respective barrier wall 275, further movement of the electronic components 1 is blocked and the position of each of the electronic components 1 is secured by the respective barrier wall 275. After the electronic components 1 are respectively secured in position by the barrier walls 275, the cam portion 521 will continue to push the transmission member 451 in the pushing direction (P). This causes the transmission member 451 to continue driving the push members 452. However, because further movement of each of the push members 452 is blocked by a respective electronic component 1, each of the push members 452 will be flexed and deformed and store a returning force. During the deformation of each of the push members 452, the area of contact between the oblique abutting surface 462 of each of the push members 452 and the respective electronic component 1 will gradually increase, and the stored returning force of each of the push members 452 will cause the oblique abutting surface 462 to abut against the respective electronic component 1 with the returning force. In this way the push members 452 and the barrier walls 275 may mitigate any accumulated position tolerance relative to the electronic component 1 and securely clamp and position the electronic components 1.

When the actuator unit 5 is rotated to the pushing position as shown in FIG. 13, the cam portion 521 of the cam 52 of the actuator unit 5 pushes the pressure bearing surface 459 of the transmission member 451, which causes the transmission member 451 and the push members 452 of the push unit 40 of the push module 4 to be in the position as shown in FIG. 13. In this way, the electronic component positioning fixture 200 may securely position and clamp the electronic components 1.

When the user desires to release the electronic components 1 from the electronic component positioning fixture 200, the user operates the assist tool to rotate the actuator unit 5 in the second rotational direction (R2). While the actuator unit 5 is being rotated in the second rotational direction (R2), the cam portion 521 will gradually move away from the pressure bearing surface 459 of the transmission member 451. The returning force stored by each of the returning elastic members 453 will act to bias the transmission member 451 and move the transmission member 451 in the direction that is opposite to the pushing direction (P) to return the transmission member to the original position thereof. While the transmission member 451 is returning to the original position, it will drive the push members 452 to respectively move away from the electronic components 1 and return to the position shown in FIG. 12. In this way, the electronic components 1 will be released from the electronic component positioning fixture 200.

By having the push unit 40 of the push module 4 made of the same material and formed as a single piece, the number of component parts used to manufacture the electronic component positioning fixture 200 may be minimized and the manufacturing costs may be reduced.

It should be noted that the second embodiment of the electronic component positioning fixture 200 may have several different variations as explained below.

In one variation of the second embodiment, the support tray 2 only has one accommodation slot 29 and one barrier wall 275, the transmission member 451 of the push unit 40 of the push module 4 only has one open slot 455, and the push unit 40 of the push module 4 only has one push member 452.

In another variation of the second embodiment, the oblique guiding surfaces 278 of the support tray 2 are omitted. This leaves the push members 452 to directly contact the respective electronic components 1.

In yet another variation of the second embodiment, the push members 452 of the push unit 40 may be a spring arm that extends from the first boundary edge 457 but that does not extend obliquely. In this case the push members 452 may be, for example, wave shaped or curve shaped.

In summary of the above, in the electronic component positioning fixture according to the present disclosure of both embodiments is able to have the push unit(s) 40 of the push module 4 be movable in the direction parallel to the plane of the support tray 2. In this way, the push module 4 may push the electronic components 1 without any component force in the vertical direction (D3), which may help to prevent the electronic components 1 from warping. Furthermore, this allows the electronic component positioning fixture 200 to securely clamp and position the electronic components 1 in the plane of the support tray 2. The actuator unit 5 is configured to drive the push unit(s) 40 to abut against the electronic components 1 so that they are able to be clamped between the push unit 40 and the barrier walls 260, 275. The actuator unit 5 is able to support the push unit(s) 40 of the push module 4 so that the push unit 40 and the barrier walls 260, 275 may securely clamp the electronic components 1. This allows each of the push members 41, 452 and the respective barrier walls 260, 275 to mitigate any accumulated tolerances relative to the respective electronic components 1 clamped therebetween. In this way, the electronic component positioning fixture 200 position the electronic components 1 with high precision.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An electronic component positioning fixture adapted to position a plurality of electronic components, said electronic component positioning fixture comprising:
a support tray adapted to support the electronic components, and including a plurality of barrier walls that are adapted to respectively block the electronic components from movement;
at least one push unit that is movably coupled to said support tray, that is capable of planar motion on said support tray, and that is adapted to push the electronic components so that the electronic components respectively abut against said barrier walls; and
an actuator unit movably coupled to said support tray;
wherein said actuator unit is configured to drive said at least one push unit to move toward and abut against the electronic components so that the electronic components respectively move towards and abut against said barrier walls and are each clamped between said at least one push unit and said barrier walls.

2. The electronic component positioning fixture as claimed in claim 1, wherein:
said actuator unit is operable to be moved between a release position and a pushing positon;
when said actuator unit is in the release position, said actuator unit does not push said at least one push unit; and
when said actuator unit is in the pushing position, said actuator unit pushes and moves said at least one push unit so that said at least one push unit abuts against the electronic components.

3. The electronic component positioning fixture as claimed in claim 1, wherein:
said support tray has a plurality of accommodation slots that are adapted to respectively receive the electronic components;
each of said barrier walls is located at a periphery of a respective one of said accommodation slots, and has a first barrier surface and a second barrier surface that are perpendicular to each other and adapted to abut against a corner of a respective one of the electronic components; and
said at least one push unit is configured to move along a pushing direction to abut against and drive the electronic components so that each of the electronic components abuts against said first barrier surface and said second barrier surface of a respective one of said barrier walls and is clamped by said at least one push unit, said first barrier surface and said second barrier surface.

4. The electronic component positioning fixture as claimed in claim 3, wherein:
said at least one push unit includes a plurality of push members, a plurality of elastic biasing members, and a transmission member, said push members being connected to said transmission member in a resiliently movable manner and respectively loaded by said elastic biasing members;
each of said push members is coupled to said support tray, movable in the pushing direction, and adapted to abut against a respective one of the electronic components along the pushing direction;
said elastic biasing members are configured to respectively abut against and apply a biasing force along the pushing direction on said push members; and
said transmission member is coupled to said support tray, being disposed between said elastic biasing members and said actuator unit, and being configured to be driven by said actuator unit to move along the pushing direction and push said elastic biasing members.

5. The electronic component positioning fixture as claimed in claim 4, wherein:
said accommodation slots are polygonal;
each of said push members is disposed at a corner of a respective one of said accommodation slots of said support tray, and has a first push surface and a second push surface that are perpendicular to each other, and that both face a respective one of said accommodation slots;
each of said barrier wall is disposed at another corner of a respective one of said accommodation slots, and is diagonally opposite to a respective one of said push members;
said first push surface and said second push surface of each of said push members are respectively parallel to said first barrier surface and said second barrier surface of a respective one of said barrier walls, and being adapted for abutting against a respective one of said electronic components.

6. The electronic component positioning fixture as claimed in claim 5, wherein:
said first push surface and said second push surface of each of said push members intersect at a first intersection corner;
said first barrier surface and said second barrier surface of each of said barrier walls intersect at a second intersection corner that is spaced apart from said first intersection corner of a respective one of said push members along an imaginary diagonal line that is parallel to the pushing direction;
each of said elastic biasing members is positioned and extends along the imaginary diagonal line linking said first intersection corner of a respective one of said push members to said second intersection corner of a respective one of said barrier walls;
each of said elastic biasing members is a compression spring that has two opposite ends respectively abutting against a respective one of said push members and said transmission member, and is deformable, extendible and compressible along the imaginary diagonal line.

7. The electronic component positioning fixture as claimed in claim 4, wherein said at least one push unit further includes at least one returning elastic member configured to apply a returning force in a direction opposite to the pushing direction for returning said transmission members to an original position thereof.

8. The electronic component positioning fixture as claimed in claim 4, wherein:
said actuator unit is a cam that is pivotally connected to said support tray for rotation about an axis perpendicular to a plane of said support tray, and that is operable to be rotated between a release position and a pushing position, and that includes a cam portion configured to drive said transmission member;
said transmission member includes a slanted surface, a deep pressure-receiving surface connected to an end of said slanted surface, and a steep stop surface that protrudes from an end of said deep pressure-receiving surface that is opposite to said slanted surface;
said cam portion of said actuator unit has a first lobe surface for pushing and sliding along said slanted surface, a shoulder surface that protrudes from and that is connected to an end of said first lobe surface for abutting against said steep stop surface, and a second lobe surface that is connected to a protruding end of said shoulder surface opposite to said first lobe surface;
when said actuator unit is in the release position, said cam portion does not abut against said transmission member, said push members do not abut against the electronic components, and said first lobe surface faces said slanted surface; and
when said actuator unit is in the pushing position, said shoulder surface abuts against said steep stop surface, said second lobe surface abuts against said deep pressure-receiving surface, and said push members respectively abut against the electronic components.

9. The electronic component positioning fixture as claimed in claim 4, wherein:
said accommodation slots are arranged to be spaced apart from each other along a lengthwise direction of said support tray;
said barrier walls are arranged to be spaced apart from each other along the lengthwise direction;
said push members of said at least one push unit are arranged to be spaced apart from each other along the lengthwise direction;
said elastic biasing members of said at least one push unit are arranged to be spaced apart from each other along the lengthwise direction; and
said transmission member of said at least one push unit is in form of an elongated plate that extends in the lengthwise direction.

10. The electronic component positioning fixture as claimed in claim 4, wherein:
said support tray has two opposite lengthwise sides;
said accommodation slots are arranged in two slot rows that each extend along the lengthwise direction, and that are spaced apart in a widthwise direction of said support tray, said accommodation slots in each of said two slot rows being arranged to be spaced apart from each other in the lengthwise direction;
each of said accommodation slots has an outer side, and an inner side opposite to said outer side, said outer sides of said accommodation slots in each of said two slot rows being proximate to a respective one of said lengthwise sides of said support tray;
said barrier walls are arranged in two barrier rows that each extends along the lengthwise direction proximate to one of said lengthwise sides of said support tray, and that are spaced apart in the widthwise direction, said barrier walls in each of said barrier rows being arranged to be spaced apart from each other in the lengthwise direction;
said at least one push unit includes two push units that are spaced apart in the widthwise direction;
said push members of each of said push units are arranged in a row that extends in the lengthwise direction;
said elastic biasing members of each of said push units are arranged in a row that extends in the lengthwise direction, said row of said elastic biasing members being spaced apart in the lengthwise direction, the pushing direction of one of said two push units being opposite to the pushing direction of the other one of said two push units;
said transmission members of said push units are in form of an elongated plate extending in the lengthwise direction, are spaced apart in the widthwise direction, are disposed between said two slot rows of said accommodation slots, and are each proximate to said inner sides of said accommodation slots; and
said actuator unit is located between said transmission members for simultaneously pushing said transmission members.

11. The electronic component positioning fixture as claimed in claim 10, wherein:
said actuator unit is a cam that is pivotally connected to said support tray for rotation about an axis perpendicular to a plane of said support tray, that is operable to be rotated between a release position and a pushing position, and that includes two cam portions that are configured to respectively drive said transmission members of said two push units;
said transmission member of each of said push units includes a slanted surface, a deep pressure-receiving surface connected to an end of said slanted surface, and a steep stop surface that is located on an end of said deep pressure-receiving surface that is opposite to said slanted surface;
each of said cam portions of said actuator unit has a first lobe surface for pushing and sliding along said slanted surface of a respective one of said push units, a shoulder surface that protrudes from and is connected to an end of said first lobe surface for abutting against said steep stop surface of a respective one of said push units, a second lobe surface that is connected to a protruding end of said shoulder surface that is opposite to said first lobe surface for pushing and sliding along said slanted surface of said respective one of said push units, and a third lobe surface connected to an end of said second lobe surface;
when said actuator unit is in the release position, said cam portion does not abut against said transmission member of each of said push units, said push members of each of said push units do not abut against the electronic components, and said first lobe surface faces said slanted surface of a respective one of said push unit; and
when said actuator unit is in the pushing position, said shoulder surface abuts against said steep stop surface of a respective one of said push units, said second lobe surface abuts against said deep pressure-receiving surface of a respective one of said push units, and said push members of said push units respectively abut against the electronic components.

12. The electronic component positioning fixture as claimed in claim 3, wherein:
said at least one push unit includes a transmission member disposed on top of said support tray, and a plurality of push members each connected to said transmission member in a resiliently movable manner;
said transmission member is configured to be driven by said actuator unit to drive movement of said push members in the pushing direction, and including a plurality of open slots that are respectively formed on top of and aligned with said accommodation slots to respectively receive the electronic components; and
each of said push members is integrally formed on said transmission member and is in form of a spring arm, said push members are respectively formed in said open slots and are configured to respectively abut against said electronic components.

13. The electronic component positioning fixture as claimed in claim 12, wherein:
said transmission member further has a plurality of open slot boundary edges which respectively define said open slots, each of said open slot boundary edges having a primary boundary edge that is located proximate to said first barrier surface of a respective one of said barrier walls, and a first boundary edge and a second boundary edge that are respectively connected to opposite ends of said primary boundary edge, said first boundary edge being located proximate to said second barrier surface of the respective one of said barrier walls; and
each of said push members extends obliquely from said first boundary edge towards said primary boundary edge and said second boundary edge of a respective one of said open slots, and has an oblique abutting surface that faces said primary boundary edge of said respective one of said open slots and that is adapted to push the electronic component.

14. The electronic component positioning fixture as claimed in claim 13, wherein:
said support tray further includes a plurality of oblique guiding surfaces each of which faces said second barrier surface of a respective one of said barrier walls and is located at an end of said first barrier surface that is opposite to said second barrier surface of said respective one of said barrier walls; and
each of said oblique guiding surfaces extends towards said first barrier surface and said second barrier surface of said respective one of said barrier walls and being configured to guide movement of the electronic component towards said first barrier surface and said second barrier surface of said respective one of said barrier walls.

15. The electronic component positioning fixture as claimed in claim 12, wherein:
said actuator unit is a cam that is pivotally connected to said support tray for rotation about an axis perpendicular to a plane of said support tray, that is operable to be rotated between a release position and a pushing position, and that includes a cam portion that is configured to drive said transmission member;
when said actuator unit is in the release position said cam portion does not push said transmission member, and said push members do not push the respective electronic components; and
when said actuator unit is in the pushing position said cam portion pushes said transmission member, and said push members respectively push the electronic components.

16. The electronic component positioning fixture as claimed in claim 15, wherein:
said transmission member includes a pressure bearing surface that is located at an end of said transmission member and that is configured to be pushed by said cam portion;
said support tray further includes a blocking post; and
said push unit further includes a returning elastic member that is disposed at another end of said transmission member opposite to said pressure bearing surface, said returning elastic member abutting against said blocking post and being configured to bias said transmission member in a direction that is opposite to the at least one pushing direction for returning said transmission member to an original position thereof.

17. The electronic component positioning fixture as claimed in claim 12, wherein said push unit is made of a same material and formed as one single piece.

18. The electronic component positioning fixture as claimed in claim 3, wherein:
said support tray further has a row of slot boundaries respectively surrounding said accommodation slots and being arranged to be spaced apart in the lengthwise direction, said first barrier surface and said second barrier surface of each of said barrier walls being located on a respective one of said slot boundaries; and
said at least one push unit has a transmission member that is in form of an elongated plate extending in the lengthwise direction, and a plurality of push members connected to said at least one push unit in a resiliently movable manner and being spaced apart in the lengthwise direction, said transmission member and said push members being movable in the pushing direction that is parallel to a plane of said support tray for pushing the electronic components against said barrier walls respectively.

19. The electronic component positioning fixture as claimed in claim 18, wherein said support tray has a cam mounting hole, said actuator unit has a cam inserted into said cam mounting hole for rotation about an axis perpendicular to a plane of said support tray, said transmission member being disposed adjacent to said cam so as to be moved by said cam for pushing said push members.

20. The electronic component positioning fixture as claimed in claim 19, wherein said support tray further has at least one guide groove that is disposed between said row of said slot boundaries and said cam mounting hole and that extends in the lengthwise direction to movably receive said transmission member of said at least one push unit, and a plurality of apertures that are each spatially communicated with said at least one guide groove and a respective one of said accommodation slots, and that respectively receive said push members and guide movements of said push members.
